(19) United States
(12) Patent Application Publication
(10) Pub. No.: US 2026/0176792 A1
(43) Pub. Date: Jun. 25, 2026

(54) STRUCTURE OF GROUP III NITRIDE SEED CRYSTAL SUBSTRATE AND METHOD FOR PRODUCING GROUP III NITRIDE CRYSTAL

(71) Applicants: The University of Osaka, Osaka (JP); PANASONIC HOLDINGS CORPORATION, Osaka (JP)

(72) Inventors: Yusuke MORI, Osaka (JP); Masashi YOSHIMURA, Osaka (JP); Masayuki IMANISHI, Osaka (JP); Kousuke MURAKAMI, Osaka (JP); Tomio YAMASHITA, Gifu (JP)

(21) Appl. No.: 19/529,695

(22) Filed: Feb. 4, 2026

Related U.S. Application Data
(63) Continuation of application No. PCT/JP2024/008683, filed on Mar. 7, 2024.

(30) Foreign Application Priority Data
Aug. 7, 2023 (JP) 2023-128650

(51) Int. Cl. C30B 29/40; C30B 25/02

(52) U.S. Cl. CPC C30B 29/406; C30B 25/02; C30B 29/403

(57) ABSTRACT

A Group III nitride seed crystal substrate for use in a method for producing a large-sized Group III nitride crystal with few defects is provided. A Group III nitride seed crystal substrate for use in a method for producing a Group III nitride crystal, includes: a substrate; and a plurality of Group III nitride seed crystals arranged over the flat surface of a main surface of the substrate.

### CROSS REFERENCE TO RELATED APPLICATION

This application claims priorities of Japanese Patent Application No. 2023-128650 filed on Aug. 7, 2023 and PCT Application No. PCT/JP2024/008683 filed on Mar. 7, 2024, the contents of which are incorporated herein by reference.

### BACKGROUND OF THE INVENTION

### 1. Field of the Invention

The present disclosure relates to a method for producing a Group III nitride

crystal, and, more particularly, to a structure of a Group III nitride seed crystal substrate when producing a Group III nitride crystal by a sodium (Na) flux method.

### 2. Description of the Related Art

Group III nitride semiconductors such as gallium nitride (also referred to as Group III nitride compound semiconductors or GaN-based semiconductors) are widely used as materials for various semiconductor elements such as laser diodes (LDs) and light-emitting diodes (LEDs). For example, laser diodes that emit blue light are applied to high-density optical disks and displays, and light-emitting diodes that emit blue light are applied to displays and lighting. Furthermore, ultraviolet LDs are expected to be applied to biotechnology and the like, and ultraviolet LEDs are expected to be used as ultraviolet sources for fluorescent lamps.

Vapor phase epitaxy, for example, is used as a method for easily producing Group III nitride semiconductor single crystals (see, for example, JP2016-69267A). However, vapor phase epitaxy has limitations on the thickness of the grown crystal, making it difficult to obtain thick Group III nitride semiconductor single crystals. For this reason, liquid phase epitaxy (LPE), in which crystals are grown in a liquid phase, is used as a method capable of growing thick films of higher quality Group III nitride semiconductor single crystals. This liquid phase epitaxy has the problem of requiring high temperatures and high pressures. To solve this problem, a technology for growing gallium nitride single crystals in Na flux (hereinafter also referred to as the “Na flux method”) has been developed (see, for example, JP2019-151519A and JP2020-132475A). This method enables thick films to be formed at relatively low temperatures and low pressures, making it suitable for mass production. The Na flux method may be, for example, a method in which a Group III nitride crystal layer that serves as a seed crystal is grown as a thin film on a sapphire substrate by metalorganic chemical vapor deposition (MOCVD), and then the Group III nitride crystal is grown as a thick film by the Na flux method. Note that metalorganic chemical vapor deposition (MOCVD) is a type of vapor phase epitaxial growth method, and in the method, it is used supplementarily to form the Group III nitride crystal layer that serves as the seed crystal. In order to effectively utilize Group III nitride crystals as materials for

semiconductor devices, the size of the Group III nitride crystals must be large enough to be viable for mass production. Furthermore, it is preferable that the Group III nitride crystals have as few defects as possible, such as distortion, dislocations, and warpage, but with conventional methods for producing Group III nitride crystals, it is extremely difficult to produce large-sized, high-quality Group III nitride crystals with few defects, such as distortion, dislocations, and warpage.

When producing a Group III nitride seed crystal by vapor phase epitaxial growth or the like, a substrate for epitaxial growth is required. Generally, an inexpensive sapphire substrate is used as this substrate. However, because the lattice constant, thermal expansion coefficient, etc. differ between the sapphire substrate and the Group III nitride crystal, defects such as distortion, dislocations, and warpage occur in the Group III nitride crystal grown on the sapphire substrate. The problem of these defects becomes more pronounced as the crystal substrate size increases.

Furthermore, in order to solve the problem of the lattice constant difference, it is conceivable to grow a Group III nitride crystal on a large-sized Group III nitride seed crystal with few defects, instead of the sapphire substrate. More specifically, for example, it is conceivable to use a Group III nitride crystal substrate as the seed crystal instead of the sapphire substrate. However, large Group III nitride seed crystals such as Group III nitride crystal substrates are very expensive, resulting in high costs. Furthermore, with conventional techniques, it is nearly impossible to obtain a large-sized, high-quality Group III nitride seed crystal with few defects such as distortion, dislocations, and warpage.

Hence, when a low-quality Group III nitride seed crystal is used, the Group III nitride crystal grown thereon will inherit the crystal defects of the seed crystal, making it difficult to fundamentally solve the problem.

Therefore, JP2019-151519A describes a method for producing a Group III nitride crystal with few defects, in which a plurality of Group III nitride crystals grown on a plurality of seed crystals formed on a substrate are bonded (coalesced) through growth. After bonding the plurality of seed crystals, the substrate is tilted and immersed in a melt and raised out of the melt plural times to flatten the crystals.

Furthermore, in JP2020-132475A, the outer shape of the arrangement of a plurality of seed crystals on the seed crystal substrate is changed by photolithography and etching so that each side of the periphery of a hexagonal region coincides with the stable (1-100) crystal plane of the Group III nitride crystal, thereby suppressing cracking of the Group III nitride crystal.

FIGS. 4A-A to 4C-B are plan views and schematic cross-sectional views showing the cross-sectional structure of each step of the method for producing a Group III nitride crystal, as described in JP2020-132475A, in which the outer shape of the arrangement of the seed crystals is a hexagon formed by the (1-100) crystal planes of the Group III nitride crystal. FIGS. 4A-A, 4B-A and 4C-A are plan views. FIGS. 4A-B, 4B-B and 4C-B are cross-sectional views seen along A-A′ direction of FIGS. 4A-A, 4B-A and 4C-A, respectively. In the method shown in FIGS. 4A-A to 4C-B, for a plurality of Group III nitride

seed crystals 12a of FIGS. 4A-A and 4A-B, a plurality of first Group III nitride crystals 12b, each having a triangular or trapezoidal cross section, are grown from a plurality of seed crystals in FIGS. 4B-A and 4B-B in accordance with the method for producing a Group III nitride crystal of JP2020-132475A. Next, as shown in FIGS. 4C-A and 4C-B, second Group III nitride crystals 12c are grown in the gaps between the plurality of first Group III nitride crystals 12b.

In the second Group III nitride crystal growth step, however, in order to grow

the second Group III nitride crystal layer 12c in the gaps between the plurality of first Group III nitride crystals 12b, the substrate is immersed in the melt and then raised out of the melt, forming a thin film of melt on the substrate surface. To obtain the thin film, the substrate is tilted at an angle of approximately 5 to 10 degrees. As shown in FIGS. 4C-A and 4C-B, a melt pool forms on an underside 12d of the tilted substrate when the substrate is raised out of the melt, resulting in a faster growth rate than in other sites. The faster growth rate on the underside of the tilted substrate results in sites where the crystal growth surface closes while still containing the melt (hereinafter referred to as inclusions) due to the difference in growth rate from the other sites. The presence of these inclusions can lead to rupture due to volume expansion caused by vaporization of the melt when the substrate is heated to 1000° C. or higher during a device fabrication process after substrate formation. In other words, conventional methods have the drawback of making it difficult to produce large-sized, high-quality Group III nitride crystals with few defects with a high yield.

### SUMMARY

The present disclosure is intended to solve the above-mentioned problems, and one non-limiting and exemplary embodiments provides a Group III nitride seed crystal substrate for use in a method for producing a large-sized Group III nitride crystal with few defects.

In one general aspect, the techniques disclosed here feature: a Group III nitride seed crystal substrate for use in a method for producing a Group III nitride crystal, includes:
a substrate; and
a plurality of Group III nitride seed crystals arranged over the flat surface of a main surface of the substrate.

In one general aspect, the techniques disclosed here feature: a method for producing a Group III nitride seed crystal substrate for use in a method for growing a Group III nitride crystal on the Group III nitride seed crystal substrate, includes:
preparing a substrate;
growing a Group III nitride seed crystal layer on the substrate; and
removing a part of the Group III nitride seed crystal layer to form a Group III nitride seed crystal substrate having a plurality of Group III nitride seed crystals arranged over the flat surface of the substrate.

In another general aspect, the techniques disclosed here feature: a method for producing a Group III nitride crystal, includes:
preparing a Group III nitride seed crystal substrate including a substrate and a plurality of Group III nitride crystals arranged as a plurality of seed crystals on the substrate; and
growing the Group III nitride crystal on the Group III nitride seed crystal substrate by repeating a plurality of times immersing of the Group III nitride seed crystal substrate into a melt and raising of the Group III nitride seed crystal substrate out of the melt in a nitrogen-containing atmosphere, the melt containing at least one Group III element selected from gallium, aluminum, and indium, and an alkali metal,
wherein in the course of preparing the Group III nitride seed crystal substrate, the plurality of seed crystals are arranged over the flat surface of a main surface of the substrate, to prepare the Group III nitride seed crystal substrate.

In the seed crystal preparation step, by arranging the plurality of Group III nitride seed crystals over the entire surface of the (0001) plane, which is the substrate's main surface, it is possible to suppress the accumulation of melt below the inclined substrate. However, if the seed crystals are arranged up to the inclined surface of the substrate edge, poor-quality crystals will grow at the substrate edge due to the influence of the inclined substrate surface, and breakage or cracks will occur from the inclined surface. Therefore, the seed crystals are not arranged on the inclined substrate surface. Since, in the first crystal growth step, lateral growth occurs up to adjacent seed crystals, it is desirable to set the seed crystals apart from the edge of the (0001) plane, which is the substrate's main surface, by a value of the arrangement distance between the seed crystals divided by 2. In the method for producing the seed crystal substrate, the seed crystals present on the inclined surface of the substrate edge may be removed by laser light irradiation, or regions may be formed by patterning and etching using resist.

According to the Group III nitride seed crystal substrate and method for producing the same, and method for producing a Group III nitride crystal of the present disclosure, it is possible to efficiently produce large-sized Group III nitride crystals with few defects.

Additional benefits and advantages of the disclosed embodiments will be apparent from the specification and figures. The benefits and/or advantages may be individually provided by the various embodiments and features of the specification and drawings disclosure, and need not all be provided in order to obtain one or more of the same.

### BRIEF DESCRIPTION OF DRAWINGS

The present disclosure will become readily understood from the following

description of non-limiting and exemplary embodiments thereof made with reference to the accompanying drawings, in which like parts are designated by like reference numeral and in which:

FIGS. 1A-A to 1D-B are plan views and schematic cross-sectional views showing cross-sectional structures, of steps of a method for producing a Group III nitride seed crystal substrate according to a first embodiment of the present invention;

FIGS. 2A-A to 2C-B are plan views and schematic cross-sectional views showing cross-sectional structures, of steps of a method for producing a Group III nitride crystal using the Group III nitride seed crystal substrate according to the first embodiment;

FIGS. 3A-A to 3D show plan views, schematic cross-sectional views showing cross-sectional structure, and a cross-sectional SEM image at a substrate edge, of steps of the method for producing a Group III nitride crystal when a plurality of seed crystals of the Group III nitride seed crystal substrate are arranged up to the edge of the substrate;

FIGS. 4A-A to 4D show plan views, schematic cross-sectional views showing cross-sectional structures, and a cross-sectional SEM image of an inclusion, of steps of the method for producing a Group III nitride crystal, as described in JP2020-132475A, in which the outer shape of the arrangement of a plurality of seed crystals on the Group III nitride seed crystal substrate is a hexagonal region;

FIG. 5A shows a PL image of the Group III nitride seed crystal substrate in which the outer shape of the arrangement of a plurality of seed crystals on the seed crystal substrate is a hexagonal region, FIG. 5B showing a PL image of the Group III nitride crystal grown on the seed crystal substrate of FIG. 5A, FIG. 5C showing a composite photograph of a photograph of the substrate after processing and an inclusion site; and

FIG. 6A shows a PL image of the Group III nitride seed crystal substrate in which the seed crystals are arranged such that the distance from the outermost periphery of the flat surface of the substrate to the center of the nearest seed crystal is less than the value obtained by multiplying the spacing between the seed crystals by 3, FIG. 6B showing a PL image of the Group III nitride crystal grown on the seed crystal substrate of FIG. 6A, FIG. 6C showing a photograph of the substrate after processing, FIG. 6D being an enlarged view of the outer peripheral edge of the seed substrate.

### DETAILED DESCRIPTION

### Background to This Disclosure

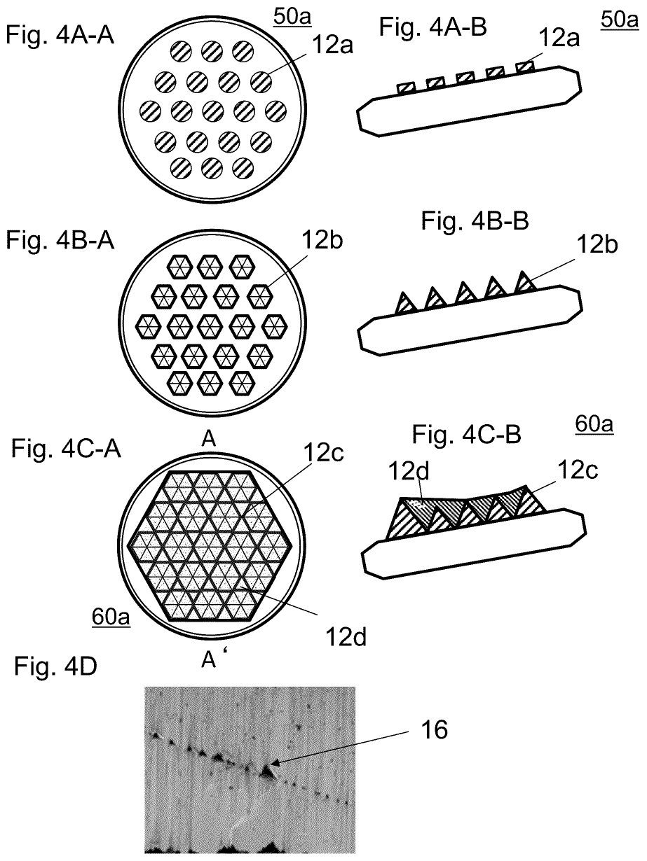

FIGS. 4A-A to 4D show plan views, schematic cross-sectional views showing cross-sectional structures, and a cross-sectional SEM image of an inclusion, of steps of the method for producing a Group III nitride crystal 60a, as described in JP2020-132475A, in which the outer shape of the arrangement of a plurality of seed crystals 12a on a Group III nitride seed crystal substrate 50a is a hexagonal region.

In JP2020-132475A, as shown in FIGS. 4A-A and 4A-B, the outer shape of the arrangement of the plural seed crystals 12a on a seed crystal substrate is a hexagonal region composed of the (1-100) crystal plane of the Group III nitride crystal. During the growth of a Group III nitride crystal, as shown in FIGS. 4B-A and 4B-B, in the first crystal growth step in which plural first Group III nitride crystals 12b, each with a triangular or trapezoidal cross section, are grown from plural seed crystals 12a, the periphery of each first Group III nitride crystal 12b is surrounded by the most stable crystal plane (the (1-100) plane in the case of GaN). In a second Group III nitride crystal growth step, as shown in FIGS. 4C-A and 4C-B, in order to grow a second Group III nitride crystal layer 12c in the gaps between the plural first Group III nitride crystals 12b, the substrate is immersed in a melt and then raised out of the melt, consequently forming a thin film of the melt on the substrate surface. To obtain a thin coating, the substrate is tilted by approximately 5 to 10 degrees, as shown in FIG. 4C-B. When the substrate is raised out of the melt, a pool of melt forms on the underside 12d of the tilted substrate, resulting in a faster growth rate than in other sites. The faster growth rate on the underside 12d of the tilted substrate results in sites where the crystal growth surface closes while still containing the melt (hereinafter referred to as an inclusion) due to the difference in growth rate from the other sites. FIG. 4D shows a cross-sectional SEM image of an inclusion 16. The presence of this inclusion 16 can lead to rupture due to volume expansion caused by vaporization of the melt when the substrate is heated to 1000° C. or higher during a device fabrication process after substrate formation. In other words, conventional methods have had the problem of making it difficult to produce large, high-quality Group III nitride crystals with few defects at a high yield.

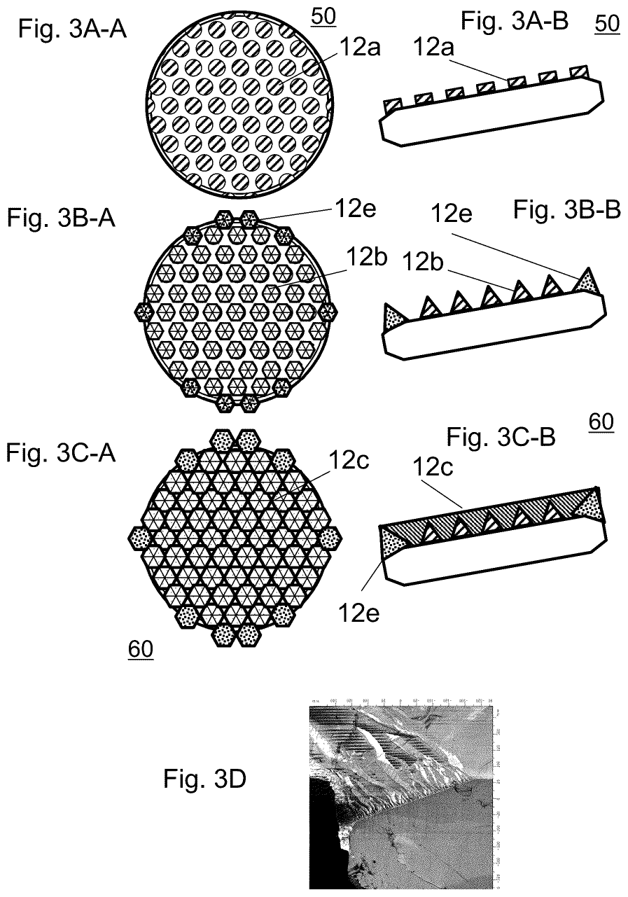

Thus, the inventors focused on the fact that the cause of the formation of the melt pool is the difference in wettability between sapphire and the Group III nitride crystal, and in order to minimize the area where the sapphire is exposed without a seed crystal, the seed crystals 12a were arranged over the entire surface of a seed crystal substrate 50 as shown in FIGS. 3A-A and 3A-B.

FIGS. 3A-A to 3D show plan views, schematic cross-sectional views showing cross-sectional structure, and a cross-sectional SEM image at a substrate edge, of steps of the method for producing a Group III nitride crystal 60 when the seed crystals 12a are placed over the entire surface of the seed crystal substrate 50.

During the growth of Group III nitride crystals, as shown in FIGS. 3B-A and 3B-B, in the first crystal growth step, a plurality of first Group III nitride crystals, each with a triangular or trapezoidal cross section, are grown from a plurality of seed crystals. During this process, miscellaneous crystals were observed in a part 12e of the outer periphery of the substrate, and cracks were generated in the crystal from that site. A cross-sectional SEM image of the miscellaneous crystals 12e is shown in FIG. 3D. It can be seen that poor-quality crystals grew at the edge of the substrate due to the influence of the inclined substrate surface, and that these were the origins of cracks and breakage. Meanwhile, because the seed crystals were positioned all the way to the edge of the substrate, an increase in film thickness due to accumulation of melt was suppressed even on the underside 12d of the inclined substrate.

From the above results, it was found that in the seed crystal preparation step, by arranging a plurality of Group III nitride seed crystals over the entire surface of the (0001) plane, which is the main surface of the substrate, it is possible to suppress the occurrence of pooling of melt below the inclined substrate.

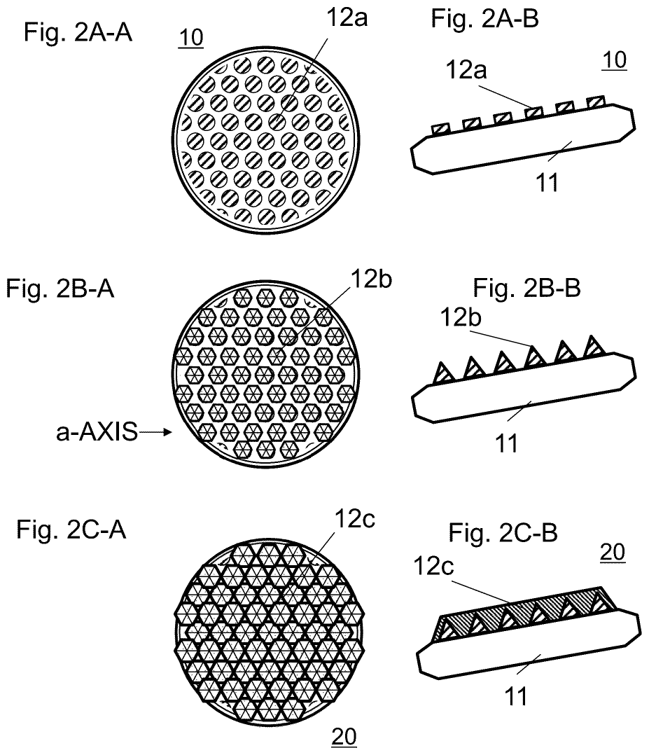

However, if the seed crystals are placed up to the inclined surface of the substrate edge, poor-quality crystals will grow at the substrate edge due to the influence of the inclined surface, and breakage or cracks will occur from that point. Therefore, it is preferable not to place seed crystals on the inclined surface of the substrate. Preferably, as shown in FIGS. 2A-A to 2C-B described later, in the first crystal growth step, lateral growth occurs to adjacent seed crystals, so the distance from the outermost periphery of the flat surface of the substrate to the center of the nearest seed crystal is made greater than the value obtained by multiplying the spacing between the seed crystals by 0.5. On the other hand, if the distance from the outermost periphery of the flat surface of the substrate to the center of the nearest seed crystal is too large, a melt pool will occur, resulting in a deterioration in substrate quality.

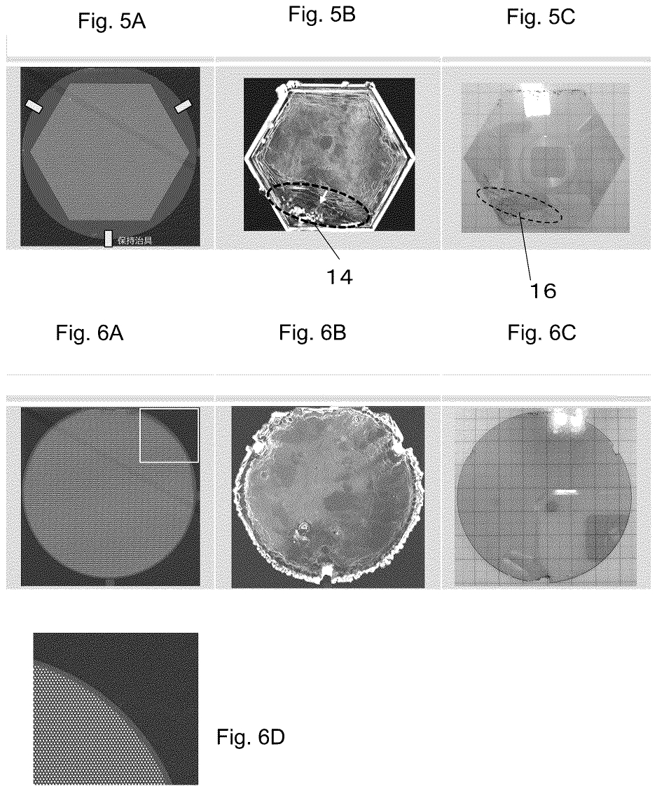

FIG. 5A shows a photoluminescence (PL) image of the Group III nitride seed crystal substrate in which the outer shape of the arrangement of the plurality of seed crystals on the seed crystal substrate is a hexagonal region, FIG. 5B showing a PL image of the Group III nitride crystal grown on the seed crystal substrate, FIG. 5C showing a composite photograph of a photograph of the substrate after processing and an inclusion site. In FIG. 5A, the bright hexagonal region is the Group III nitride seed crystal region, and the slightly darker region around it is the sapphire substrate. FIG. 5B is a PL image of a Group III nitride crystal grown using the seed crystal substrate. The underside of the tilted substrate corresponds to the underside of the PL image, and it can be seen that a melt pool 14 has occurred. FIG. 5C is a composite photograph of a photograph of the substrate after processing and an inclusion site (denoted by reference numeral 16 in the figure). As shown, the inclusion 16 corresponding to the melt pool site is observed.

FIG. 6A shows a PL image of the Group III nitride seed crystal substrate in which the seed crystals are arranged such that the distance from the outermost periphery of the flat surface of the substrate to the center of the nearest seed crystal is less than the value obtained by multiplying the spacing between the seed crystals by 3, FIG. 6B showing a PL image of the Group III nitride crystal grown on the seed crystal substrate of FIG. 6A, FIG. 6C showing a photograph of the substrate after processing, FIG. 6D being an enlarged view of the outer peripheral edge of the seed substrate. It can be seen from the PL image after crystal growth that there are no melt pools, and that there are no inclusions even after substrate processing. Furthermore, as shown in FIG. 6D, it can be seen that no seed crystals are arranged at the outer peripheral edge of the seed substrate.

In other words, it was found that by using a Group III nitride seed crystal substrate in which a plurality of Group III nitride seed crystals are arranged across the entire flat surface of the substrate, rather than across the entire surface of the substrate, it is possible to obtain large-sized Group III nitride crystals that are free of melt pools and inclusions.

Based on the above findings, the inventors have arrived at a Group III nitride seed crystal substrate and a method for producing the same, as well as a method for producing a Group III nitride crystal according to the present disclosure. Aspects of the present disclosure will be described below.

A Group III nitride seed crystal substrate for use in a method for producing a

Group III nitride crystal according to a first aspect, includes:
a substrate; and
a plurality of Group III nitride seed crystals arranged over the flat surface of a main surface of the substrate.

In the Group III nitride seed crystal substrate according to a second aspect in addition to the first aspect, each of the plurality of Group III nitride seed crystals may have a dot-shaped, have a size of 10 to 1000μm, and the plurality of Group III nitride seed crystals may be arranged such that a pitch, which is the distance between centers of adjacent two Group III nitride seed crystals, may be 1.5 to 10 times the size.

In the Group III nitride seed crystal substrate according to a third aspect in addition to the first or second aspect, the plurality of Group III nitride seed crystals may form a triangular lattice.

A method for producing a Group III nitride seed crystal substrate for use in a method for growing a Group III nitride crystal on the Group III nitride seed crystal substrate according to a fourth aspect, includes:
preparing a substrate;
growing a Group III nitride seed crystal layer on the substrate; and
removing a part of the Group III nitride seed crystal layer to form a Group III nitride seed crystal substrate having a plurality of Group III nitride seed crystals arranged over the flat surface of the substrate.

In the method for producing a Group III nitride seed crystal substrate according to a fifth aspect in addition to the fourth aspect, in the course of removing a part of the Group III nitride seed crystal layer, each of the plurality of Group III nitride seed crystals may have a dot-shaped, have a size of 10 to 1000 μm, and the plurality of Group III nitride seed crystals may be arranged such that a pitch, which is the distance between centers of adjacent two Group III nitride seed crystals, may be 1.5 to 10 times the size.

In the method for producing a Group III nitride seed crystal substrate according to a sixth aspect in addition to the fourth or fifth aspect, in the course of removing a part of the Group III nitride seed crystal layer, the plurality of Group III nitride seed crystals may form a triangular lattice.

A method for producing a Group III nitride crystal according to a seventh aspect, includes:
preparing a Group III nitride seed crystal substrate including a substrate and a plurality of Group III nitride crystals arranged as a plurality of seed crystals on the substrate; and
growing the Group III nitride crystal on the Group III nitride seed crystal substrate by repeating a plurality of times immersing of the Group III nitride seed crystal substrate into a melt and raising of the Group III nitride seed crystal substrate out of the melt in a nitrogen-containing atmosphere, the melt containing at least one Group III element selected from gallium, aluminum, and indium, and an alkali metal,
wherein in the course of preparing the Group III nitride seed crystal substrate, the plurality of seed crystals are arranged over the flat surface of a main surface of the substrate, to prepare the Group III nitride seed crystal substrate.

In the method for producing a Group III nitride crystal according to an eighth aspect in addition to the seventh aspect, in the course of preparing the Group III nitride seed crystal substrate, the flat surface of the main surface of the substrate may be a (0001) plane.

In the method for producing a Group III nitride crystal according to a ninth aspect in addition to the seventh or eighth aspect, in the course of preparing the Group III nitride seed crystal substrate, the Group III nitride seed crystals may be arranged only on the flat surface of the substrate excluding the outer peripheral edge of the substrate.

In the method for producing a Group III nitride crystal according to a tenth aspect in addition to any one of the seventh to ninth aspects, the step of preparing the Group III nitride seed crystal substrate may include removing the Group III nitride seed crystal located at the outer peripheral edge of the substrate other than the flat surface of the substrate.

In the method for producing a Group III nitride crystal according to an eleventh aspect in addition to the tenth aspect, in the course of preparing the Group III nitride seed crystal substrate, the distance from the outermost periphery of the flat surface of the substrate to the center of the nearest Group III nitride seed crystal may be equal to or greater than the value obtained by multiplying the spacing between the Group III nitride seed crystals by 0.5 and equal to or less than the value obtained by multiplying the spacing between the Group III nitride seed crystals by 3.

In the method for producing a Group III nitride crystal according to a twelfth aspect in addition to the tenth aspect, in the course of preparing the Group III nitride seed crystal substrate, the distance from the outermost periphery of the flat surface of the substrate to the center of the nearest Group III nitride seed crystal may be greater than 0.3 mm and equal to or less than 1.6 mm.

In the method for producing a Group III nitride crystal according to a thirteenth aspect in addition to any one of the seventh to twelfth aspects, in the course of preparing the Group III nitride seed crystal substrate, each of the plurality of Group III nitride seed crystals may have a dot-shaped, have a size of 10 to 1000 μm, and the plurality of Group III nitride seed crystals may be arranged such that a pitch, which is the distance between centers of adjacent two Group III nitride seed crystals, may be 1.5 to 10 times the size of the Group III nitride seed crystal.

In the method for producing a Group III nitride crystal according to a fourteenth aspect in addition to any one of the seventh to thirteenth aspects, in the course of preparing the Group III nitride seed crystal substrate, the plurality of Group III nitride seed crystals form a triangular lattice.

In the Group III nitride seed crystal substrate according to a fifteenth aspect in addition to any one of the first to third aspects, the plurality of Group III nitride seed crystals may be arranged over the entire flat surface of a main surface of the substrate.

In the Group III nitride seed crystal substrate according to a sixteenth aspect in addition to any one of the first to third, and fifteenth aspects, the plurality of Group III nitride seed crystals may be arranged such that the distance from the outermost periphery of the flat surface of the substrate to the center of the nearest Group III nitride seed crystal may be equal to or greater than the value obtained by multiplying the spacing between the Group III nitride seed crystals by 0.5 and equal to or less than the value obtained by multiplying the spacing between the Group III nitride seed crystals by 3.

In the Group III nitride seed crystal substrate according to a seventeenth aspect in addition to any one of the first to third, fifteenth, and sixteenth aspects, the plurality of Group III nitride seed crystal substrate may be arranged such that the distance from the outermost periphery of the flat surface of the substrate to the center of the nearest Group III nitride seed crystal is greater than 0.3 mm and equal to or less than 1.6 mm.

Hereinafter, a Group III nitride seed crystal substrate and a method for producing the same, and a method for producing a Group III nitride crystal according to the present disclosure will be described with reference to the accompanying drawings.

### First Embodiment)

### Regarding Production Method (Preparation Step) of Group III Nitride Seed Crystal Substrate

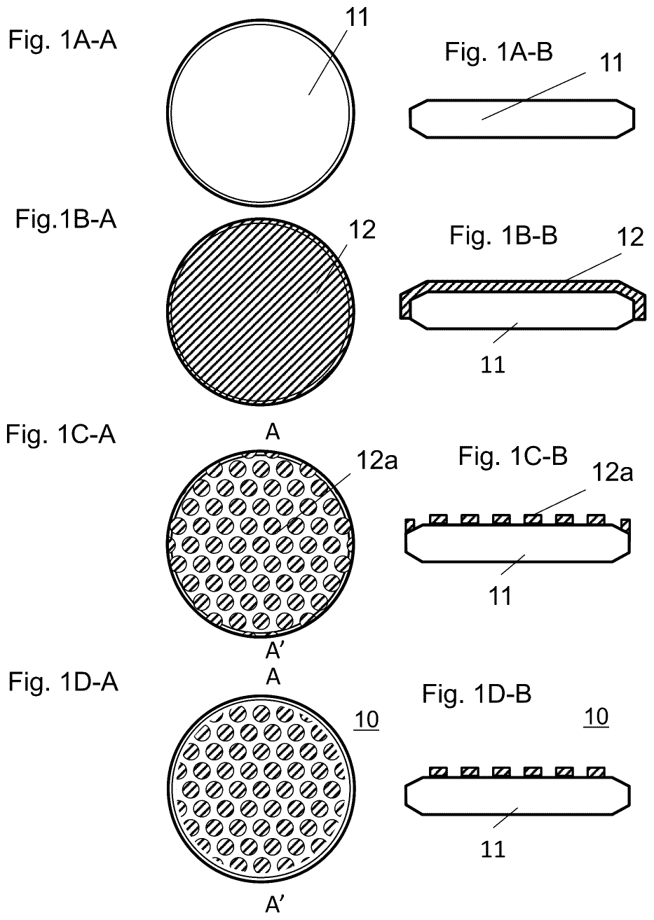

FIGS. 1A-A to 1D-B are plan views and schematic cross-sectional views showing cross-sectional structures, of steps of a method for producing a Group III nitride seed crystal substrate 10 according to a first embodiment.
(1) First, as shown in FIGS. 1A-A and 1A-B, a sapphire substrate 11 is prepared as a substrate for a Group III nitride seed substrate used in a Group III nitride crystal production method. Sapphire is preferable because its lattice constant and thermal expansion coefficient differ relatively little from those of GaN. In addition to sapphire, other materials such as SiC, GaAs, and ScAlMgO₄ may also be used as the substrate 11. The thickness of the substrate 11 is preferably approximately 100 to 2000 μm, and more preferably 400 to 1000 μm. A thickness within this range ensures sufficient strength and reduces the risk of cracking during GaN crystal fabrication. The shape of the substrate 11 is not particularly limited, but considering industrial practicality, a wafer-like shape with a diameter of approximately 50 to 200 mm is preferred. As shown in the schematic cross-sectional view of FIG. 1A-B, the outer peripheral edge of the substrate is chamfered to prevent chipping in subsequent processes.
(2) Next, as shown in FIGS. 1B-A and 1B-B, a thin film (Group III nitride seed crystal layer) 12 made of single crystal GaN is formed on the substrate 11 made of sapphire by MOCVD. The thickness of the thin film is preferably of the order of 0.5 to 100 μm, and more preferably 1 to 5 μm. If the thickness of the thin film is 0.5 μm or more, the formed thin film will be a good single crystal, and lattice defects and the like will be less likely to occur in the resulting GaN crystal. The dislocation density of the GaN thin film formed on sapphire by MOCVD is generally of the order of 10⁷/cm² to 10⁹/cm².

If necessary, a buffer layer (not shown) may be further formed between the substrate 11 and the thin film 12. The buffer layer is a layer for forming a high-quality GaN single crystal thin film on the sapphire substrate 11 and for buffering the difference in lattice constant between sapphire and GaN. The buffer layer is preferably made of a material with a lattice constant close to that of sapphire and GaN, and may be a layer made of a Group III nitride such as GaN. The buffer layer is preferably an amorphous or polycrystalline layer grown by MOCVD at a relatively low temperature between 400° C. and 700° C. inclusive. The use of such a buffer layer reduces the occurrence of lattice defects in the GaN single crystal thin film formed on the buffer layer. The thickness of the buffer layer is preferably between 10 nm and 50 nm inclusive, more preferably between 20 nm and 40 nm inclusive. A buffer layer thickness of 10 nm or more effectively buffers the lattice constant difference, reducing the occurrence of lattice defects in the resulting GaN crystal. On the other hand, if the buffer layer is too thick, the information of the crystal lattice of the substrate 11 made of sapphire is lost, making it impossible to achieve good epitaxial growth.
(3) Next, a part of the thin film made of GaN single crystals is removed by a

known method such as photolithography and etching to form a plurality of seed crystals 12a made of a plurality of GaN crystals. The method for removing the part of the thin film made of GaN single crystals is not limited to photolithography and etching. For example, the removal may be performed by laser light irradiation. The seed crystals 12a may have a shape of plural dots, stripes, or the like. The seed crystals 12a are preferably dot-shaped. The size (diameter) of each dot is preferably approximately 10 to 1000 μm, more preferably 50 to 300 μm. The dots are preferably arranged so that the line connecting the centers of two adjacent dots approximately coincides with the crystal orientation (a-axis or m-axis) of the hexagonal GaN. The dots are preferably arranged in a triangular lattice, as shown in FIGS. 1C-A and 1C-B, and are preferably arranged so that the centers of each dot form the vertices of an equilateral triangle when viewed from above. In this specification, the line connecting the centers of two adjacent dots substantially coincides with the crystal orientation (a-axis or m-axis) of GaN means that the angle between the line connecting the centers of the dots (the axis of the triangular lattice) and the crystal orientation (a-axis or m-axis) of GaN is 10 degrees or less, and these angles are preferably 1 degree or less.

Furthermore, the dot pitch (the distance between centers) is preferably about 1.5 to 10 times the dot size (diameter), and more preferably 2 to 5 times. The dot shape is preferably circular or hexagonal. When the dot size, arrangement, pitch, and shape are as described above, initial pyramidal crystal growth and bonding of pyramidal crystals (GaN crystals) together become easier when growing GaN crystals by the flux method. Another effect is that dislocations inherited from the seed crystal can be efficiently reduced.

From the results of FIGS. 6A to 6D, the arrangement of the seed crystals 12a is desirably such that the distance from the outermost periphery of the flat surface of substrate 11 to the center of the nearest seed crystal 12a is equal to or greater than the value obtained by multiplying the spacing between the seed crystals 12 a by 0.5 and equal to or less than the value obtained by multiplying the spacing between the seed crystals 12a by 5. More preferably, the distance is equal to or less than the value obtained by multiplying the spacing between the seed crystals 12 a by 3.
(4) As shown in FIGS. 1D-A and 1D-B, the seed crystals present on the

inclined surface at the edge of the substrate 11 are removed by physical processing. The physical processing is not particularly limited, and examples thereof include cutting, or processing by colliding particles or waves with the Group III nitride seed crystal layer. Alternatively, regions may be formed by patterning and etching using a resist, as will be described later. Among these, processing by colliding particles or waves with the Group III nitride seed crystal layer is preferred. Examples of processing by colliding particles or waves with the Group III nitride seed crystal layer include laser light irradiation, particle (ion or electron) beam irradiation, milling, shot blasting, and ultrasonic processing. Among these, laser light irradiation is particularly preferred. This is because laser light irradiation enables precise processing to be performed more easily. Specifically, for example, laser light may be irradiated onto a site desired to be removed of the Group III nitride seed crystal layer. The wavelength of the laser light is not particularly limited, but is preferably a wavelength that can remove the site desired to be removed of the Group III nitride seed crystal layer without affecting the substrate. To this end, the wavelength of the laser light is preferably a wavelength that is absorbed by the Group III nitride seed crystal layer and transmitted through the substrate. When the substrate is a sapphire substrate and the Group III nitride seed crystal layer is GaN, for example, a laser light having a wavelength of 1030 nm can be used.

Next, in the case of the patterning and etching method using resist, the region of the Group III nitride seed crystal layer corresponding to a site where crystal growth of the Group III nitride crystal is desired is covered with a mask such as resist, and the sites not covered with the mask are dry-etched using a chlorine-based gas. Once removal of the Group III nitride seed crystal layer at the outer periphery of the seed substrate is completed by dry etching, the resist or other mask is peeled off. As another method, a mask may be used on the thin film 12 made of GaN single crystal shown in FIGS. 1C-A and 1C-B to limit the growth region.

In this manner, the Group III nitride seed crystal substrate 10 can be obtained.

### An Example of Method for Producing Group III Nitride Crystal

FIGS. 2A-A to 2C-B are plan views and schematic cross-sectional views showing cross-sectional structures, of steps of a method for producing a Group III nitride crystal 20 using the Group III nitride seed crystal substrate 10 according to the first embodiment.
(1) FIGS. 2A-A and 2A-B show the Group III nitride seed crystal substrate 10 produced by the method for producing a Group III nitride seed crystal substrate. The method for producing the Group III nitride crystal 20 according to the first embodiment uses the above Group III nitride seed crystal substrate 10 shown in FIGS. 1C-A and 1C-B obtained by the method for producing a Group III nitride seed crystal substrate according to the first embodiment shown in FIGS. 1A-A to 1D-B.

In the step of growing the Group III nitride crystal, for example, a flux containing sodium is placed in a reaction vessel made of alumina, and the Group III nitride crystal is grown by the Na flux method.
(2) As shown in FIGS. 2B-A and 2B-B, in the first crystal growth step, the plurality of first Group III nitride crystals 12b, each having a triangular or trapezoidal cross section, are grown on a plurality of seed crystals. The periphery of each of these first Group III nitride crystals 12b is surrounded by the most stable crystal plane (the (1-100) plane in the case of GaN).
(3) In the second Group III nitride crystal growth step, as shown in FIGS. 2C-A and 2C-B, a thin film of the melt is formed on the surface of the substrate by immersing the substrate in the melt and then raising the substrate out of the melt, in order to grow Group III nitride crystal layers 12c in the gaps between the plurality of first Group III nitride crystals 12b. To obtain the thin film, the substrate is tilted at an angle of, for example, approx. 5 to 10 degrees, as shown in FIG. 2C-B.

In this manner, a large-sized Group III nitride crystal 20 with few defects is obtained.

In the obtained Group III nitride crystal, the dislocation distribution appearing on the surface reflects the pattern of the plural seed crystals of the Group III nitride seed crystal substrate used. Thus, by measuring the dislocation distribution on the surface of the Group III nitride crystal, the arrangement pattern of the plural seed crystals of the Group III nitride seed crystal substrate used can be estimated.

The Group III element is gallium (Ga) and/or aluminum (Al). One type of the Group III element may be used alone, or two types may be used in combination. The Group III nitride crystal is preferably a gallium nitride (GaN) single crystal or an aluminum nitride (AlN) single crystal.

In the above method for producing a Group III nitride crystal 20, the Group III nitride seed crystal substrate 10 is prepared in advance as shown in FIGS. 2A-A and 2A-B, the flux is brought into contact with the substrate, and a new first Group III nitride crystal 12b is grown using the Group III nitride seed crystal 12a as a nucleus as shown in FIGS. 2B-A and 2B-B. The most notable feature of this production method is that it can rapidly produce a large-sized single crystal. That is, in this method, the first Group III nitride crystal 12b is grown and enlarged on the Group III nitride seed crystal 12a that serves as the nucleus as shown in FIGS. 2B-A and 2B-B, and a second Group III nitride crystal 12c is grown as shown in FIGS. 2C-A and 2C-B, thereby bonding adjacent Group III nitride crystals together, thereby obtaining a large single crystal.

In the above method for producing Group III nitride crystals, gallium nitride single crystals can be grown using a flux containing at least sodium metal. A gallium source material is dissolved in this flux. The gallium source material can be gallium metal, a gallium alloy, or a gallium compound, but gallium metal is preferred for ease of handling. The ratio of the gallium source material to the flux source material, such as sodium, can be any ratio; however, an excess amount of sodium is generally used, and the composition ratio (mol % ratio) of the flux is preferably Ga:Na=20:80 to 40:60. In the Group III nitride crystal growth step, the growth conditions for the Group III nitride crystals are, for example, a temperature of 100 to 1500° C. and a pressure of 100 Pa to 20 MPa, preferably a temperature of 300 to 1200° C. and a pressure of 0.01 to 10 MPa, and more preferably a temperature of 500 to 1100° C. and a pressure of 0.1 to 6 MPa.

The nitrogen-containing gas is, for example, nitrogen (N₂) gas, ammonia (NH₃) gas, or the like, and these may be mixed, with no limitations on the mixing ratio.

Hereinafter, Example 1 will be described more specifically with respect to a Group III nitride seed crystal substrate and a method for producing a Group III nitride crystal using the same.

### EXAMPLE 1

The Group III nitride seed crystal substrate and the method for producing a Group III nitride crystal according to Example 1 will be described in the order of steps.

### An Example of Group III Nitride Seed Crystal Substrate and Its Production Method

(1) First, as shown in FIGS. 1A-A and 1A-B, the substrate 11 is prepared. The substrate used is a sapphire substrate having a diameter of 7.5 cm and a thickness of 1000 μm.
(2) Next, as shown in FIGS. 1B-A and 1B-B, a thin film 12 made of single

crystal GaN is formed to a thickness of 5 μm by MOCVD on the substrate 11 made of sapphire. Note that a commercially available Group III nitride seed crystal substrate may be used as the nucleus for such growth.
(3) As shown in FIGS. 1C-A and 1C-B, a part of the gallium nitride is removed

by irradiation with a laser beam having a wavelength of 1030 nm to form a plurality of Group III nitride seed crystals 12a. For example, a laser beam having a wavelength of 1030 nm may be irradiated onto the site of the gallium nitride to be removed. The shape of the Group III nitride seed crystals 12 a is processed into a circle having a diameter of 0.2 mm, and the distance between the centers of adjacent seed crystals 12 a is 0.6 mm. The plurality of Group III nitride seed crystals 12a are arranged such that the a-axes of the crystals generated and grown on the various adjacent crystals substantially overlap each other.
(4) In FIGS. 1D-A and 1D-B, unnecessary Group III nitride seed crystal layers

on the outer periphery of the substrate are removed by the laser light irradiation process as described above. The distance from the outermost periphery of the flat surface of the substrate to the center of the nearest seed crystal is set to be greater than the value obtained by multiplying the spacing between the seed crystals by 0.5 and less than the value obtained by multiplying the spacing by 3. In the case of the above seed crystal arrangement, a region of 1.8 mm is removed from the outermost periphery of the flat surface of the substrate.

Through the above steps, the Group III nitride seed crystal layer is removed from the inclined parts around the periphery of the substrate, obtaining a Group III nitride seed crystal substrate in which the region of the Group III nitride seed crystal layer is disposed in a region spaced 1.8 mm or more from the outermost periphery of the flat surface of the substrate.

### An Example of Method for Producing Group III Nitride Crystal

(1) The Group III nitride crystal is produced using the Group III nitride seed crystal substrate described above. FIGS. 2A-A and 2A-B show a Group III nitride seed crystal substrate produced by the Group III nitride seed crystal substrate producing method.

The Group III nitride crystal growth process involves growing crystals by the Na flux method in an alumina reaction vessel containing a sodium-containing flux. The Na flux is prepared in a glove box with an argon atmosphere. Metallic sodium of 250 g, metallic gallium of 275 g, and carbon of 0.9 g as an additive are mixed in an alumina crucible, which serves as the growth vessel. The substrate is then loaded into the alumina crucible along with the Na flux, and the Na flux is confined within the space of the alumina crucible with an alumina lid. The alumina crucible, which serves as the reaction vessel, is then sealed with a stainless steel container. Once the Na flux is ready, the stainless steel growth vessel is removed from the glove box and quickly placed inside the growth apparatus, and the growth apparatus containing the growth vessel is then evacuated. Vacuuming is performed thoroughly to evacuate the space within the growth apparatus and remove moisture from the insulation. Next, nitrogen is filled to a nitrogen pressure of 3 to 5 MPa, which is the growth condition for gallium nitride. To keep the nitrogen pressure constant, nitrogen is flowed at 1 slm while the pressure inside the container is controlled to 3 to 5 MPa. Next, the temperature inside the growth container is raised to 800 to 900° C. Once the target temperature is reached, the temperature inside the container is maintained.
(2) In the first crystal growth step, a seed crystal substrate is immersed in Na

flux while tilted at an angle of 5 degrees for 10 to 50 hours to grow the plurality of first Group III nitride crystals 12b of gallium nitride (GaN) each having a triangular or trapezoidal cross section from a plurality of seed crystals, as shown in FIGS. 2B-A and 2B-B. In plan view, the a-axes of the crystals generated and grown on various adjacent crystals substantially overlap each other.
(3) Next, referring to FIGS. 2C-A and 2C-B, in order to grow Group III nitride crystals in the gaps between the plurality of first Group III nitride crystals 12b, a substrate is immersed in the melt and then raised out of the melt, forming a thin film of melt on the substrate surface. Regarding the time period for immersing the substrate in the melt and the time period for raising the substrate out of the melt, it is preferable to keep the immersion time period of the substrate in the low-supersaturation melt as short as possible. On the other hand, it is efficient to set the time period for raising the substrate out of the melt to the time period required for Ga in the film-like melt to be depleted. The immersion time period is preferably 0 to 30 minutes, and the raising time period is preferably 1 to 60 minutes. An immersion time period of 0 minutes means that the substrate is raised out of the melt immediately after immersion in the melt. Even in the case of an immersion time period of 0 minutes, the substrate is still immersed in the melt. In other words, 0 minutes means that the time period in which the substrate remains in the melt is essentially 0 minutes. Specifically, it means that the substrate is raised out of the melt immediately after reaching below the melt surface. Therefore, 0 minutes may include, for example, a time period measured in seconds. Furthermore, in order to suppress the generation of polycrystals, the temperature in the second Group III nitride crystal growth step is preferably set to, for example, of the order of 3 to 50° C. higher than the temperature in the first Group III nitride crystal growth step, and is set to 850 to 900° C. By repeating this immersion in the melt and raised out of the melt 100 to 300 times, second Group III nitride crystal layers 12c grow between the first Group III nitride crystal layers 12b, bonding the Group III nitride crystal layers 12b to each other, suppressing cracking of the substrate and obtaining a high-quality film with few defects.

The Group III nitride seed crystal substrate according to the present disclosure makes it possible to produce large-sized Group III nitride crystals with few defects for use in white LEDs and semiconductor laser diodes used in lighting, automobile headlights, and the like.

### REFERENCE SIGNS LIST

10 Group III nitride seed crystal substrate
11 substrate
12 Group III nitride seed crystal layer
12a Group III nitride seed crystal
12b first Group III nitride crystal
12c second Group III nitride crystal layer
12d tilted underside of second Group III nitride crystal layer
14 melt pool
16 inclusion
20 Group III nitride crystal
50, 50a Group III nitride seed crystal substrate
60, 60a Group III nitride crystal

What is claimed is

1. A Group III nitride seed crystal substrate for use in a method for producing a Group III nitride crystal, comprising:
a substrate; and
a plurality of Group III nitride seed crystals arranged over the flat surface of a main surface of the substrate.

2. The Group III nitride seed crystal substrate according to claim 1,
wherein each of the plurality of Group III nitride seed crystals has a dot-shaped, has a size of 10 to 1000 μm, and the plurality of Group III nitride seed crystals are arranged such that a pitch, which is the distance between centers of adjacent two Group III nitride seed crystals, is 1.5 to 10 times the size.

3. The Group III nitride seed crystal substrate of claim 1,
wherein the plurality of Group III nitride seed crystals form a triangular lattice.

4. A method for producing a Group III nitride seed crystal substrate for use in a method for growing a Group III nitride crystal on the Group III nitride seed crystal substrate, comprising:
preparing a substrate;
growing a Group III nitride seed crystal layer on the substrate; and
removing a part of the Group III nitride seed crystal layer to form a Group III nitride seed crystal substrate having a plurality of Group III nitride seed crystals arranged over the flat surface of the substrate.

5. The method for producing a Group III nitride seed crystal substrate according to claim 4,
wherein in the course of removing a part of the Group III nitride seed crystal layer, each of the plurality of Group III nitride seed crystals has a dot-shaped, has a size of 10 to 1000 μm, and the plurality of Group III nitride seed crystals are arranged such that a pitch, which is the distance between centers of adjacent two Group III nitride seed crystals, is 1.5 to 10 times the size.

6. The method for producing a Group III nitride seed crystal substrate according to claim 4,
wherein in the course of removing a part of the Group III nitride seed crystal layer, the plurality of Group III nitride seed crystals form a triangular lattice.

7. A method for producing a Group III nitride crystal, comprising:
preparing a Group III nitride seed crystal substrate including a substrate and a plurality of Group III nitride crystals arranged as a plurality of seed crystals on the substrate; and
growing the Group III nitride crystal on the Group III nitride seed crystal substrate by repeating a plurality of times immersing of the Group III nitride seed crystal substrate into a melt and raising of the Group III nitride seed crystal substrate out of the melt in a nitrogen-containing atmosphere, the melt containing at least one Group III element selected from gallium, aluminum, and indium, and an alkali metal,
wherein in the course of preparing the Group III nitride seed crystal substrate, the plurality of seed crystals are arranged over the flat surface of a main surface of the substrate, to prepare the Group III nitride seed crystal substrate.

8. The method for producing a Group III nitride crystal according to claim 7,
wherein in the course of preparing the Group III nitride seed crystal substrate, the flat surface of the main surface of the substrate is a (0001) plane.

9. The method for producing a Group III nitride crystal according to claim 7,
wherein in the course of preparing the Group III nitride seed crystal substrate, the Group III nitride seed crystals are arranged only on the flat surface of the substrate excluding the outer peripheral edge of the substrate.

10. The method for producing a Group III nitride crystal according to claim 7,
wherein the step of preparing the Group III nitride seed crystal substrate comprises removing the Group III nitride seed crystal located at the outer peripheral edge of the substrate other than the flat surface of the substrate.

11. The method for producing a Group III nitride crystal according to claim 10,
wherein in the course of preparing the Group III nitride seed crystal substrate, the distance from the outermost periphery of the flat surface of the substrate to the center of the nearest Group III nitride seed crystal is equal to or greater than the value obtained by multiplying the spacing between the Group III nitride seed crystals by 0.5 and equal to or less than the value obtained by multiplying the spacing between the Group III nitride seed crystals by 3.

12. The method for producing a Group III nitride crystal according to claim 10,
wherein in the course of preparing the Group III nitride seed crystal substrate, the distance from the outermost periphery of the flat surface of the substrate to the center of the nearest Group III nitride seed crystal is greater than 0.3 mm and equal to or less than 1.6 mm.

13. The method for producing a Group III nitride crystal according to claim 7,
wherein in the course of preparing the Group III nitride seed crystal substrate, each of the plurality of Group III nitride seed crystals has a dot-shaped, has a size of 10 to 1000 μm, and the plurality of Group III nitride seed crystals are arranged such that a pitch, which is the distance between centers of adjacent two Group III nitride seed crystals, is 1.5 to 10 times the size of the Group III nitride seed crystal.

14. The method for producing a Group III nitride crystal according to claim 7,
wherein in the course of preparing the Group III nitride seed crystal substrate, the plurality of Group III nitride seed crystals form a triangular lattice.

15. The Group III nitride seed crystal substrate according to claim 1,
wherein the plurality of Group III nitride seed crystals are arranged over the entire flat surface of a main surface of the substrate.

16. The Group III nitride seed crystal substrate according to claim 1,
wherein the plurality of Group III nitride seed crystals are arranged such that the distance from the outermost periphery of the flat surface of the substrate to the center of the nearest Group III nitride seed crystal is equal to or greater than the value obtained by multiplying the spacing between the Group III nitride seed crystals by 0.5 and equal to or less than the value obtained by multiplying the spacing between the Group III nitride seed crystals by 3.

17. The Group III nitride seed crystal substrate according to claim 1,
wherein the plurality of Group III nitride seed crystal substrate are arranged such that the distance from the outermost periphery of the flat surface of the substrate to the center of the nearest Group III nitride seed crystal is greater than 0.3 mm and equal to or less than 1.6 mm.
